(19) United States
(12) Patent Application Publication
(10) Pub. No.: US 2004/0253378 A1
(43) Pub. Date: Dec. 16, 2004

(54) Stress reduction of SIOC low k film by addition of alkylenes to OMCTS based processes

(75) Inventors: Francimar C. Schmitt, Santa Clara, CA (US); Hichem M'Saad, Santa Clara, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/461,638

(22) Filed: Jun. 12, 2003

(51) Int. Cl. C23C 16/00

(52) U.S. Cl. 427/255.28; 427/568

(57) ABSTRACT

A method for depositing a low dielectric constant film having a dielectric constant of about 3.2 or less, preferably about 3.0 or less, includes providing a cyclic organosiloxane and a linear hydrocarbon compound having at least one unsaturated carbon-carbon bond to a substrate surface. In one aspect, the cyclic organosiloxane and the linear hydrocarbon compound are reacted at conditions sufficient to deposit a low dielectric constant film on the semiconductor substrate. Preferably, the low dielectric constant film has compressive stress.

### BACKGROUND OF THE DISCLOSURE

1. Field of the Invention

Embodiments of the present invention relate to the fabrication of integrated circuits. More particularly, embodiments of the present invention relate to a process for depositing dielectric layers on a substrate.

2. Background of the Invention

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.13 μm and even 0.1 μm feature sizes, and tomorrow's facilities soon will be producing devices having even smaller feature sizes.

The continued reduction in device geometries has generated a demand for films having lower dielectric constant (k) values because the capacitive coupling between adjacent metal lines must be reduced to further reduce the size of devices on integrated circuits. In particular, insulators having low dielectric constants, less than about 4.0, are desirable. Examples of insulators having low dielectric constants include spin-on glass, such as un-doped silicon glass (USG) or fluorine-doped silicon glass (FSG), silicon dioxide, and polytetrafluoroethylene (PTFE), which are all commercially available.

More recently, organosilicon films having k values less than about 3.5 have been developed. Rose et al. (U.S. Pat. No. 6,068,884) disclosed a method for depositing an insulator by partially fragmenting a cyclic organosilicon compound to form both cyclic and linear structures in the deposited film. However, this method of partially fragmenting cyclic precursors is difficult to control and thus, product consistency is difficult to achieve.

Furthermore, while organosilicon films having desirable dielectric constants have been developed, many known low dielectric organosilicon films have undesirable physical or mechanical properties, such as high tensile stress. High tensile stress in a film can lead to film bowing or deformation, film cracking, film peeling, or the formation of voids in the film, which can damage or destroy a device that includes the film.

There is a need, therefore, for a controllable process for making lower dielectric constant films that have desirable physical or mechanical properties.

### SUMMARY OF THE INVENTION

Embodiments of the invention include a method for depositing a low dielectric constant film having a dielectric constant less than 3.2 by delivering a gas mixture including a cyclic organosiloxane, a linear hydrocarbon compound having at least one unsaturated carbon-carbon bond, and at least one noble gas to a substrate surface at conditions sufficient to deposit a film on the substrate surface. In one aspect, the deposited film has compressive stress. In one embodiment, the cyclic organosiloxane is octamethylcyclotetrasiloxane (OMCTS) and the linear hydrocarbon compound is ethylene. The deposited film may be treated with an electron beam.

Embodiments of the invention also include delivering a gas mixture including a cyclic organosiloxane, a linear hydrocarbon compound having at least one unsaturated carbon-carbon bond, one or more oxidizing gases, and at least one noble gas to a substrate surface at conditions sufficient to deposit a film on the substrate surface, wherein the film has a dielectric constant less than 3.2 and compressive stress. In one aspect, the deposited film is treated with an electron beam.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the description and appended drawings illustrate only typical embodiments of this invention and are therefore not to be considered limiting of its scope, for the invention may admit to other equally effective embodiments.

FIG. 1 is a cross-sectional diagram of an exemplary CVD reactor configured for use according to embodiments described herein.

FIG. 2 is an electron beam chamber in accordance with an embodiment of the invention.

FIG. 3 is a fragmentary view of the electron beam chamber in accordance with an embodiment of the invention.

FIG. 4 illustrates the electron beam chamber with a feedback control circuit in accordance with an embodiment of the invention.

### DETAILED DESCRIPTION OF THE PREFERRED EMBODIMENTS

Embodiments of the invention provide low stress in low dielectric constant films containing silicon, oxygen, and carbon by providing a cyclic organosiloxane, a linear hydrocarbon compound having at least one unsaturated carbon-carbon bond, and optionally, one or more oxidizing gases at conditions sufficient to deposit a film having a dielectric constant less than 3.2. Preferably, the film is deposited at conditions providing a dielectric constant less than 3.0 and compressive stress. A film that has compressive stress has a stress of less than 0 Mpa, as measured by a FSM 128L tool, available from Frontier Semiconductor, San Jose, Calif. More generally, conditions that provide compressive stress are determined by depositing a conformal film on a flat silicon substrate. If the conformal film bows down after deposition, i.e., the film edge is pulled lower than the film center, the process conditions introduced compressive stress.

The cyclic organosiloxane includes compounds having one or more silicon-carbon bonds. Commercially available cyclic organosiloxane compounds that include one or more rings having alternating silicon and oxygen atoms with one or two alkyl groups bonded to the silicon atoms may be used. For example, the cyclic organosiloxane may be one of the following compounds:

1,3,5,7-tetramethylcyclotetrasiloxane (TMCTS), —(—SiHCH₃—O—)₄— (cyclic)

octamethylcyclotetrasiloxane (OMCTS), —(—Si(CH₃)₂—O—)₄— (cyclic)

1,3,5,7,9-pentamethylcyclopentasiloxane, —(—SiHCH₃—O—)₅— (cyclic)

hexamethylcyclotrisiloxane, —(—Si(CH₃)₂—O—)₃— (cyclic)

decamethylcyclopentasiloxane —(—Si(CH₃)₂—O—)₅— (cyclic).

A blend of two or more of the cyclic organosiloxanes may also be used.

The cyclic organosiloxane is mixed with a linear hydrocarbon compound having at least one unsaturated carbon-carbon bond. The unsaturated carbon-carbon bond may be a double bond or a triple bond. The linear hydrocarbon compound may include one or two carbon-carbon double bonds. As defined herein, a “linear hydrocarbon compound” includes hydrogen and carbon atoms, but does not include oxygen, nitrogen, or fluorine atoms. Preferably, the linear hydrocarbon compound includes only carbon and hydrogen atoms. The linear hydrocarbon compound may be an alkene, alkylene, or diene having two to about 20 carbon atoms, such as ethylene, propylene, isobutylene, acetylene, allylene, ethylacetylene, 1,3-butadiene, isoprene, 2,3-dimethyl-1,3-butadiene, and piperylene.

In any of the embodiments described herein, the gas mixtures may essentially exclude or may include one or more oxidizing gases selected from oxygen (O₂), ozone (O₃), nitrous oxide (N₂O), carbon monoxide (CO), carbon dioxide (CO₂), water (H₂O), and combinations thereof. In one aspect, the oxidizing gas is oxygen gas. In another aspect, the oxidizing gas is oxygen gas and carbon dioxide. In another aspect, the oxidizing gas is ozone. When ozone is used as an oxidizing gas, an ozone generator converts from 6% to 20%, typically about 15%, by weight of the oxygen in a source gas to ozone, with the remainder typically being oxygen. However, the ozone concentration may be increased or decreased based upon the amount of ozone desired and the type of ozone generating equipment used. The one or more oxidizing gases may be added to the reactive gas mixture to increase reactivity and achieve the desired carbon content in the deposited film.

During deposition, a blend/mixture of a cyclic organosiloxane and a linear hydrocarbon compound having at least one unsaturated carbon-carbon bond is reacted to form a low k film on the substrate. Optionally, one or more oxidizing gases are included in the blend/mixture. One or more carrier gases, such as argon, helium, or combinations thereof may be included in the blend/mixture.

The films contain a carbon content between about 5 and about 30 atomic percent (excluding hydrogen atoms), preferably between about 5 and about 20 atomic percent. The carbon content of the deposited films refers to atomic analysis of the film structure which typically does not contain significant amounts of non-bonded hydrocarbons. The carbon contents are represented by the percent of carbon atoms in the deposited film, excluding hydrogen atoms which are difficult to quantify. For example, a film having an average of one silicon atom, one oxygen atom, one carbon atom, and two hydrogen atoms has a carbon content of 20 atomic percent (one carbon atom per five total atoms), or a carbon content of 33 atomic percent excluding hydrogen atoms (one carbon atom per three total atoms).

In any of the embodiments described herein, after the low dielectric constant film is deposited, the film may be treated with an electron beam (e-beam) to reduce the dielectric constant of the film. The electron beam treatment typically has a dose between about 50 and about 2000 micro coulombs per square centimeter (μc/cm²) at about 1 to 20 kiloelectron volts (KeV). The e-beam current typically ranges from about 1 mA to about 40 mA, and is preferably about 10 to about 20 mA. The e-beam treatment is typically operated at a temperature between about room-temperature and about 450° C. for about 10 seconds to about 15 minutes. In one aspect, the e-beam treatment conditions include 6 kV, 10-18 mA and 50 μc/cm² at 350° C. for about 15 to about 30 seconds to treat a film having a thickness of about 1 micron. In another aspect, the e-beam treatment conditions include 4.5 kV, 10-18 mA and 50 pc/cm² at 350° C. for about 15 to about 30 seconds to treat a film having a thickness of about 5000 Å. Argon or hydrogen may be present during the electron beam treatment. Although any e-beam device may be used, one exemplary device is the EBK chamber, available from Applied Materials, Inc. Treating the low dielectric constant film with an electron beam after the low dielectric constant film is deposited will volatilize at least some of the organic groups in the film which may form voids in the film.

Alternatively, in another embodiment, after the low dielectric constant film is deposited, the film is post-treated with an annealing process to reduce the dielectric constant of the film. Preferably, the film is annealed at a temperature between about 200° C. and about 400° C. for about 2 seconds to about 1 hour, preferably about 30 minutes. A non-reactive gas such as helium, hydrogen, nitrogen, or a mixture thereof is introduced at a rate of 100 to about 10,000 sccm. The chamber pressure is maintained between about 2 Torr and about 10 Torr. The RF power is about 200 W to about 1,000 W at a frequency of about 13.56 MHz, and the preferable substrate spacing is between about 300 mils and about 800 mils.

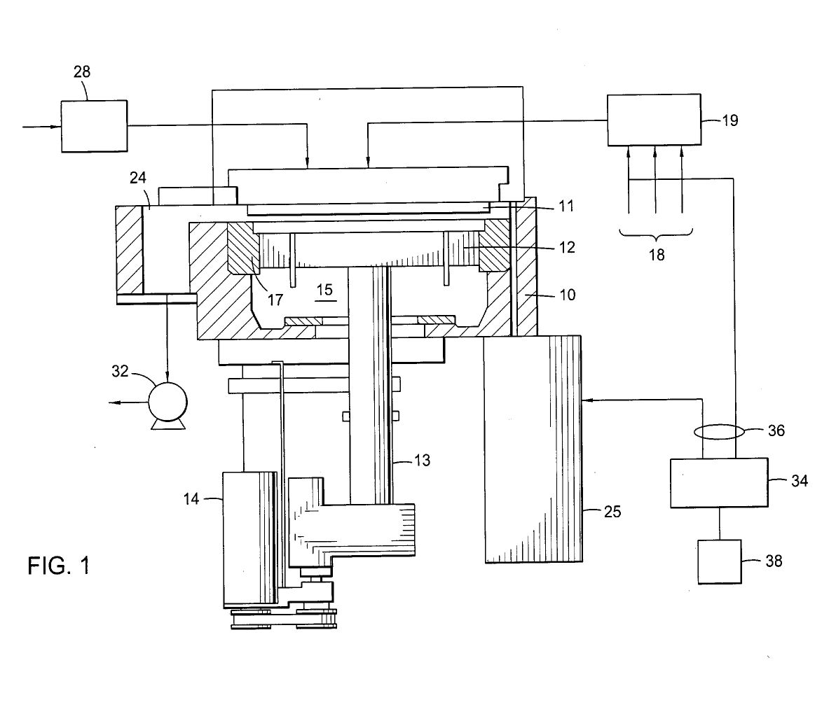

The film may be deposited using any processing chamber capable of chemical vapor deposition (CVD). For example, FIG. 1 shows a vertical, cross-section view of a parallel plate CVD processing chamber 10. The chamber 10 includes a high vacuum region 15 and a gas distribution manifold 11 having perforated holes for dispersing process gases there-through to a substrate (not shown). The substrate rests on a substrate support plate or susceptor 12. The susceptor 12 is mounted on a support stem 13 that connects the susceptor 12 to a lift motor 14. The lift motor 14 raises and lowers the susceptor 12 between a processing position and a lower, substrate-loading position so that the susceptor 12 (and the substrate supported on the upper surface of susceptor 12) can be controllably moved between a lower loading/off-loading position and an upper processing position which is closely adjacent to the manifold 11. An insulator 17 surrounds the susceptor 12 and the substrate when in an upper processing position.

Gases introduced to the manifold 11 are uniformly distributed radially across the surface of the substrate. A vacuum pump 32 having a throttle valve controls the exhaust rate of gases from the chamber 10 through a manifold 24. Deposition and carrier gases, if needed, flow through gas lines 18 into a mixing system 19 and then to the manifold 11. Generally, each process gas supply line 18 includes (i) safety shut-off valves (not shown) that can be used to automatically or manually shut off the flow of process gas into the chamber, and (ii) mass flow controllers (also not shown) to measure the flow of gas through the gas supply lines 18. When toxic gases are used in the process, several safety shut-off valves are positioned on each gas supply line 18 in conventional configurations.

In one aspect, the cyclic organosiloxane is introduced to the mixing system 19 at a flowrate of about 75 sccm to about 500 sccm. The linear hydrocarbon compound having at least one unsaturated carbon-carbon bond is introduced to the mixing system 19 at a flowrate of about 200 sccm to about 5,000 sccm. The optional oxidizing gas has a flowrate of about 0 sccm to about 200 sccm. The carrier gas has a flowrate of about 100 sccm to about 5,000 sccm. Preferably, the cyclic organosilicon compound is octamethylcyclotetrasiloxane, and the linear hydrocarbon compound is ethylene.

The deposition process is preferably a plasma enhanced process. In a plasma enhanced process, a controlled plasma is typically formed adjacent the substrate by RF energy applied to the gas distribution manifold 11 using a RF power supply 25. Alternatively, RF power can be provided to the susceptor 12. The RF power to the deposition chamber may be cycled or pulsed to reduce heating of the substrate and promote greater porosity in the deposited film. The power density of the plasma for a 200 or 300 mm substrate is between about 0.03 W/cm² and about 3.2 W/cm², which corresponds to a RF power level of about 10 W to about 1,000 W for a 200 mm substrate and about 20 W to about 2,250 W for a 300 mm substrate. Preferably, the RF power level is between about 200 W and about 1,700 W for a 300 mm substrate.

The RF power supply 25 can supply a single frequency RF power between about 0.01 MHz and 300 MHz. Preferably, the RF power may be delivered using mixed, simultaneous frequencies to enhance the decomposition of reactive species introduced into the high vacuum region 15. In one aspect, the mixed frequency is a lower frequency of about 12 kHz and a higher frequency of about 13.56 mHz. In another aspect, the lower frequency may range between about 300 Hz to about 1,000 kHz, and the higher frequency may range between about 5 mHz and about 50 mHz. Preferably, the low frequency power level is about 150 W. Preferably, the high frequency power level is about 200 W and about 750 W, more preferably, about 200 W to about 400 W.

During deposition, the substrate is maintained at a temperature between about −20° C. and about 500° C., preferably between about 100° C. and about 450° C. The deposition pressure is typically between about 1 Torr and about 20 Torr, preferably between about 4 Torr and about 7 Torr. The deposition rate is typically between about 3,000 Å/min and about 15,000 Å/min.

When additional dissociation of the oxidizing gas is desired, an optional microwave chamber 28 can be used to input power from between about 50 Watts and about 6,000 Watts to the oxidizing gas prior to the gas entering the processing chamber 10. The additional microwave power can avoid excessive dissociation of the organosilicon compounds prior to reaction with the oxidizing gas. A gas distribution plate (not shown) having separate passages for the organosilicon compound and the oxidizing gas is preferred when microwave power is added to the oxidizing gas.

Typically, any or all of the chamber lining, distribution manifold 11, susceptor 12, and various other reactor hardware is made out of materials such as aluminum or anodized aluminum. An example of such a CVD reactor is described in U.S. Pat. No. 5,000,113, entitled “A Thermal CVD/PECVD Reactor and Use for Thermal Chemical Vapor Deposition of Silicon Dioxide and In-situ Multi-step Planarized Process,” which is incorporated by reference herein.

A system controller 34 controls the motor 14, the gas mixing system 19, and the RF power supply 25 which are connected therewith by control lines 36. The system controller 34 controls the activities of the CVD reactor and typically includes a hard disk drive, a floppy disk drive, and a card rack. The card rack contains a single board computer (SBC), analog and digital input/output boards, interface boards, and stepper motor controller boards. The system controller 34 conforms to the Versa Modular Europeans (VME) standard which defines board, card cage, and connector dimensions and types. The VME standard also defines the bus structure having a 16-bit data bus and 24-bit address bus. The system controller 34 operates under the control of a computer program stored on a hard disk drive 38.

The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in susceptor design, heater design, location of RF power connections and others are possible. For example, the substrate could be supported and heated by a resistively heated susceptor.

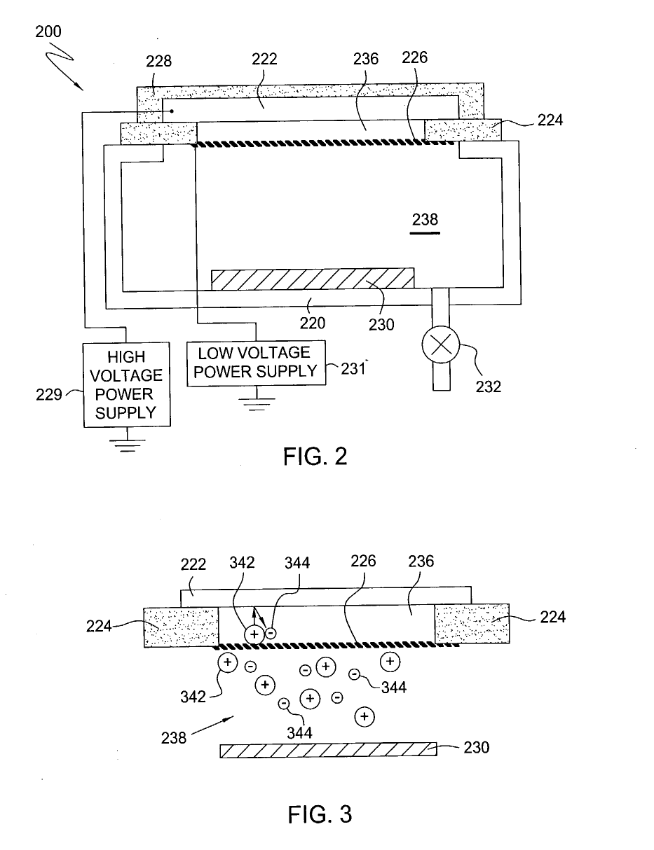

Once the film is deposited, the substrate may be transferred to an electron beam (e-beam) apparatus for further processing, i.e., curing. The substrate may be transferred with vacuum break or under vacuum, i.e., without any vacuum break. FIG. 2 illustrates an e-beam chamber 200 in accordance with an embodiment of the invention. The e-beam chamber 200 includes a vacuum chamber 220, a large-area cathode 222, a target plane 230 located in a field-free region 238, and a grid anode 226 positioned between the target plane 230 and the large-area cathode 222. The e-beam chamber 200 further includes a high voltage insulator 224, which isolates the grid anode 226 from the large-area cathode 222, a cathode cover insulator 228 located outside the vacuum chamber 220, a variable leak valve 232 for controlling the pressure inside the vacuum chamber 220, a variable high voltage power supply 229 connected to the large-area cathode 222, and a variable low voltage power supply 231 connected to the grid anode 226.

In operation, the substrate (not shown) to be exposed with the electron beam is placed on the target plane 230. The vacuum chamber 220 is pumped from atmospheric pressure to a pressure in the range of about 1 mTorr to about 200 mTorr. The exact pressure is controlled by the variable rate leak valve 232, which is capable of controlling pressure to about 0.1 mTorr. The electron beam is generally generated at a sufficiently high voltage, which is applied to the large-area cathode 222 by the high voltage power supply 229. The voltage may range from about −500 volts to about 30,000 volts or higher. The high voltage power supply 229 may be a Bertan Model #105-30R manufactured by Bertan of Hickville, N.Y., or a Spellman Model #SL30N-1200×258 manufactured by Spellman High Voltage Electronics Corp., of Hauppauge, N.Y. The variable low voltage power supply 231 applies a voltage to the grid anode 226 that is positive relative to the voltage applied to the large-area cathode 222. This voltage is used to control electron emission from the large-area cathode 222. The variable low voltage power supply 231 may be an Acopian Model #150PT12 power supply available from Acopian of Easton, Pa.

To initiate electron emission, the gas in the field-free region 238 between the grid anode 226 and the target plane 30 must become ionized, which may occur as a result of naturally occurring gamma rays. Electron emission may also be artificially initiated inside the vacuum chamber 220 by a high voltage spark gap. Once this initial ionization takes place, positive ions 342 (shown in FIG. 3) are attracted to the grid anode 226 by a slightly negative voltage, i.e., on the order of about 0 to about −200 volts, applied to the grid anode 226. These positive ions 342 pass into the accelerating field region 236, disposed between the large-area cathode 222 and the grid anode 226, and are accelerated towards the large-area cathode 222 as a result of the high voltage applied to the large-area cathode 222. Upon striking the large-area cathode 222, these high-energy ions produce secondary electrons 344, which are accelerated back toward the grid anode 226. Some of these electrons 344, which travel generally perpendicular to the cathode surface, strike the grid anode 226, but many of these electrons 344 pass through the grid anode 226 and travel to the target plane 230. The grid anode 226 is preferably positioned at a distance less than the mean free path of the electrons emitted by the large-area cathode 222, e.g., the grid anode 226 is preferably positioned less than about 4 mm from the large-area cathode 222. Due to the short distance between the grid anode 226 and the large-area cathode 222, no, or minimal if any, ionization takes place in the accelerating field region 236 between the grid anode 226 and the large-area cathode 222.

In a conventional gas discharge device, the electrons would create further positive ions in the accelerating field region, which would be attracted to the large-area cathode 222, creating even more electron emission. The discharge could easily avalanche into an unstable high voltage breakdown. However, in accordance with an embodiment of the invention, the ions 342 created outside the grid anode 226 may be controlled (repelled or attracted) by the voltage applied to the grid anode 226. In other words, the electron emission may be continuously controlled by varying the voltage on the grid anode 226. Alternatively, the electron emission may be controlled by the variable leak valve 232, which is configured to raise or lower the number of molecules in the ionization region between the target plane 230 and the large-area cathode 222. The electron emission may be entirely turned off by applying a positive voltage to the grid anode 226, i.e., when the grid anode voltage exceeds the energy of any of the positive ion species created in the space between the grid anode 226 and target plane 230.

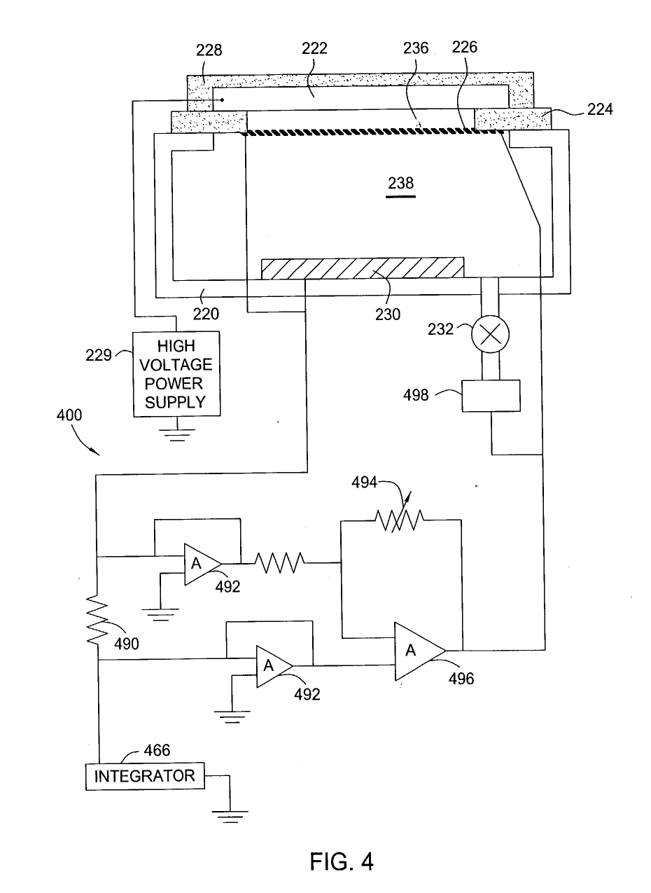

FIG. 4 illustrates the e-beam chamber 200 with a feedback control circuit 400. In some applications it may be desirable to provide a constant beam current at different electron beam energies. For example, it may be desirable to expose or cure the upper layer of the film formed on the substrate, but not the bottom layer. This may be accomplished by lowering the electron beam energy such that most of the electrons are absorbed in the upper layer of the film. Subsequent to curing the top layer, it may be desirable to cure the full thickness of the film. This can be done by raising the accelerating voltage of electron beam to penetrate completely through the film. The feedback control circuit 400 is configured to maintain a constant beam current independent of changes in the accelerating voltage. The feedback control circuit 400 includes an integrator 466. The beam current is sampled via a sense resistor 490, which is placed between the target plane 230 and the integrator 466. The beam current may also be sampled at the grid anode 226 as a portion of the beam is intercepted there. Two unity gain voltage followers 492 buffer the signal obtained across the sense resistor 490 and feed it to an amplifier 496 with a variable resistor 494. The output of this amplifier controls the voltage on the grid anode 226 such that an increase in beam current will cause a decrease in bias voltage on the grid anode 226 and a decrease in beam current from the large-area cathode 222. The gain of the amplifier 496 is adjusted, by means of the variable resistor 494, so that any change in beam current caused by a change in the accelerating voltage is counteracted by a change in bias voltage, thereby maintaining a constant beam current at the target. Alternatively, the output of the amplifier 496 may be connected to a voltage controlled variable rate leak valve 298 to counteract changes in beam current by raising or lowering the pressure in the ionization region 238. Further, a wider range of beam current control may be provided by utilizing feedback signals to both the variable leak valve 298 and the grid anode 226. Other details of the e-beam chamber 200 are described in U.S. Pat. No. 5,003,178, entitled “Large-Area Uniform Electron Source”, issued to William R. Livesay, assigned to Electron Vision Corporation (which is currently owned by the assignee of the present invention) and is incorporated by reference herein to the extent not inconsistent with the invention.

### EXAMPLES

The following examples illustrate the low dielectric films of the present invention. The films were deposited using a chemical vapor deposition chamber that is part of an integrated processing platform. In particular, the films were deposited using a Producer® 300 mm system, available from Applied Materials, Inc. of Santa Clara, Calif.

### Example 1

A low dielectric constant film was deposited on a 300 mm substrate from the following reactive gases at a chamber pressure of about 6 Torr and substrate temperature of about 350° C.

Octamethylcyclotetrasiloxane (OMCTS), at about 215 sccm;

Ethylene, at about 800 sccm; and

Helium, at about 1,000 sccm

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 4,709 Å/min, and had a dielectric constant (k) of about 2.99 measured at 0.1 MHz. The film had a compressive stress of −9.23 MPa.

### Example 2

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 800 sccm; and

Helium, at about 750 sccm;

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 5,052 Å/min, and had a dielectric constant (k) of about 2.99 measured at 0.1 MHz. The film had a compressive stress of −5.61 MPa.

### Example 3

A low dielectric constant film was deposited on a 300 mm substrate from the following reactive gases at a chamber pressure of about 5 Torr and substrate temperature of about 350° C.

Octamethylcyclotetrasiloxane (OMCTS), at about 257 sccm;

Ethylene, at about 800 sccm; and

Helium, at about 1,000 sccm

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 4,963 Å/min, and had a dielectric constant (k) of about 2.98 measured at 0.1 MHz. The film had a compressive stress of −1.69 MPa.

### Example 4

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 800 sccm; and

Helium, at about 1,000 scorn

The substrate was positioned 300 mils from the gas distribution showerhead. A power level of about 200 W at a frequency of 13.56 MHz and a power level of about 150 W at a frequency of 350 kHz were applied to the showerhead for plasma enhanced deposition of the film. The film was deposited at a rate of about 3,339 Å/min, and had a dielectric constant (k) of about 2.97 measured at 0.1 MHz. The film had a compressive stress of −19.22 MPa.

### Example 5

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 1,200 sccm; and

Helium, at about 1,000 sccm

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 4,814 Å/min, and had a dielectric constant (k) of about 3.07 measured at 0.1 MHz. The film had a compressive stress of −15.02 MPa.

### Example 6

A low dielectric constant film was deposited on a 300 mm substrate from the following reactive gases at a chamber pressure of about 5 Torr and substrate temperature of 350° C.

Octamethylcyclotetrasiloxane (OMCTS), at about 321 sccm;

Argon, at about 3,000 sccm;

Ethylene, at about 1,000 sccm; and

Helium, at about 1,000 sccm

The substrate was positioned 300 mils from the gas distribution showerhead. A power level of 750 W at a frequency of 13.56 MHz and a power level of about 150 W at a frequency of 350 kHz were applied to the showerhead for plasma enhanced deposition of the film. The deposited film had a dielectric constant (k) of about 3.15 measured at 0.1 MHz. The film had a compressive stress of −1.76 MPa.

### Comparison Example 1

A low dielectric constant film was deposited on a 300 mm substrate from the following reactive gases at a chamber pressure of about 5 Torr and substrate temperature of 350° C.

Octamethylcyclotetrasiloxane (OMCTS), at about 298 sccm;

Ethylene, at about 800 sccm; and

Helium, at about 1,000 sccm

The substrate was positioned 300 mils from the gas distribution showerhead. A power level of 400 W at a frequency of 13.56 MHz and a power level of about 150 W at a frequency of 350 kHz were applied to the showerhead for plasma enhanced deposition of the film. The film was deposited at a rate of about 4,825 Å/min, and had a dielectric constant (k) of about 2.94 measured at 0.1 MHz. The film had a tensile stress of 3.23 MPa.

### Comparison Example 2

A low dielectric constant film was deposited on a 300 mm substrate from the following reactive gases at a chamber pressure of about 5 Torr and substrate temperature of 350° C.

Octamethylcyclotetrasiloxane (OMCTS), at about 340 sccm;

Ethylene, at about 800 sccm; and

Helium, at about 1,000 sccm

The substrate was positioned 300 mils from the gas distribution showerhead. A power level of 400 W at a frequency of 13.56 MHz and a power level of about 150 W at a frequency of 350 kHz were applied to the showerhead for plasma enhanced deposition of the film. The film was deposited at a rate of about 4,472 Å/min, and had a dielectric constant (k) of about 2.91 measured at 0.1 MHz. The film had a tensile stress of 5.16 MPa.

### Example 7

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 2,400 sccm;

Oxygen, at about 160 sccm; and

Helium, at about 1,000 sccm

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 4,479 Å/min, and had a dielectric constant (k) of about 2.99 measured at 0.1 MHz. The film had a compressive stress of −3.34 MPa.

### Example 8

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 2,800 sccm;

Oxygen, at about 160 sccm; and

Helium, at about 1,000 sccm

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 4,322 Å/min, and had a dielectric constant (k) of about 3.00 measured at 0.1 MHz. The film had a compressive stress of −5.8 MPa.

### Example 9

A low dielectric constant film was deposited on a 300 mm substrate from the following reactive gases at a chamber pressure of about 5 Torr and substrate temperature of about 350° C.

Octamethylcyclotetrasiloxane (OMCTS), at about 200 sccm;

Ethylene, at about 5,000 sccm; and

Oxygen, at about 100 sccm

Helium, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 3,679 Å/min, and had a dielectric constant (k) of about 3.14 measured at 0.1 MHz. The film had a compressive stress of −82 MPa.

### Example 10

A low dielectric constant film was deposited on a 300 mm substrate from the following reactive gases at a chamber pressure of about 5 Torr and substrate temperature of about 350° C.

Octamethylcyclotetrasiloxane (OMCTS), at about 200 sccm;

Ethylene, at about 4,000 sccm; and

Oxygen, at about 100 sccm

Helium, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 4,011 Å/min, and had a dielectric constant (k) of about 3.10 measured at 0.1 MHz. The film had a compressive stress of −38 MPa.

### Example 11

A low dielectric constant film was deposited on a 300 mm substrate from the following reactive gases at a chamber pressure of about 5 Torr and substrate temperature of about 350° C.

Octamethylcyclotetrasiloxane (OMCTS), at about 200 sccm;

Ethylene, at about 3,200 sccm; and

Oxygen, at about 100 sccm

Helium, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 4,291 Å/min, and had a dielectric constant (k) of about 3.07 measured at 0.1 MHz. The film had a compressive stress of −27 MPa.

### Example 12

A low dielectric constant film was deposited on a 300 mm substrate from the following reactive gases at a chamber pressure of about 5 Torr and substrate temperature of about 350° C.

Octamethylcyclotetrasiloxane (OMCTS), at about 200 sccm;

Ethylene, at about 1,600 sccm; and

Oxygen, at about 100 sccm

Helium, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 5,163 Å/min, and had a dielectric constant (k) of about 2.96 measured at 0.1 MHz. The film had a compressive stress of −3 MPa.

### Comparison Example 3

A low dielectric constant film was deposited on a 300 mm substrate from the following reactive gases at a chamber pressure of about 5 Torr and substrate temperature of about 350° C.

Octamethylcyclotetrasiloxane (OMCTS), at about 200 sccm;

Ethylene, at about 800 sccm; and

Oxygen, at about 100 sccm

Helium, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,061 Å/min, and had a dielectric constant (k) of about 2.86 measured at 0.1 MHz. The film had a tensile stress of 8 MPa.

### Comparison Example 4

A low dielectric constant film was deposited on a 300 mm substrate from the following reactive gases at a chamber pressure of about 5 Torr and substrate temperature of about 350° C.

Octamethylcyclotetrasiloxane (OMCTS), at about 215 sccm;

Ethylene, at about 800 sccm; and

Oxygen, at about 160 sccm

Helium, at about 1,000 scorn

The substrate was positioned 300 mils from the gas distribution showerhead. A power level of about 400 W at a frequency of 13.56 MHz and a power level of about 150 W at a frequency of 350 kHz were applied to the showerhead for plasma enhanced deposition of the film. The film was deposited at a rate of about 5,810 Å/min, and had a dielectric constant (k) of about 2.93 measured at 0.1 MHz. The film had a tensile stress of 23.46 MPa.

Examples 1-6 and comparison Examples 1 and 2 show the processing conditions that were used to deposit low dielectric constant films from gas mixtures that included OMCTS, ethylene, and oxygen. The films of Examples 1-6 had dielectric constants of less than 3.2 and compressive stress. The films of Comparison Examples 1 and 2 also had dielectric constants of less than 3.2. However, the films of Comparison Examples 1 and 2 had tensile stress, rather than compressive stress. As defined herein, a film that has tensile stress is a film that has a stress of greater than 0 Mpa, as measured by a FSM 128L tool.

It is believed that the lower flow rate of OMCTS, i.e., 257 scorn or less, used in Examples 1-5 than in the Comparison Examples 1 and 2 may contribute to the compressive stress of the films in Examples 1-5. It is believed that the higher flow rate of OMCTS in Example 6 does not result in a film with tensile stress because a higher flowrate of ethylene and a flow of an additional carrier gas, argon, diluted the amount of OMCTS in the gas mixture of Example 6.

Examples 7-12 and comparison Examples 3 and 4 show the processing conditions that were used to deposit low dielectric constant films from gas mixtures that included OMCTS and ethylene. The films of Examples 7-12 had dielectric constants of less than 3.2 and compressive stress. The films of Comparison Examples 3 and 4 also had dielectric constants of less than 3.2. However, the films of Comparison Examples 3 and 4 had tensile stress, rather than compressive stress.

It is believed that the higher flow rate of ethylene, i.e., greater than about 800 sccm, used in Examples 7-12 than in the Comparison Examples 3 and 4 may contribute to the compressive stress of the films in Examples 7-12.

While the foregoing is directed to preferred embodiments of the present invention, other and further embodiments of the invention may be devised without departing from the basic scope thereof, and the scope thereof is determined by the claims which follow.

What is claimed is:

1. A method for depositing a low dielectric constant film, comprising:
delivering a gas mixture consisting essentially of:
a cyclic organosiloxane;
a linear hydrocarbon compound having at least one unsaturated carbon-carbon bond to a substrate surface; and
an inert gas; and
applying RF power to the gas mixture at conditions sufficient to deposit a film on the substrate surface, the film having a dielectric constant less than 3.2.

2. The method of claim 1, wherein the film has compressive stress.

3. The method of claim 1, wherein the cyclic organosiloxane comprises one or more silicon-carbon bonds.

4. The method of claim 3, wherein the cyclic organosiloxane is octamethylcyclotetrasiloxane (OMCTS).

5. The method of claim 1, wherein cyclic organosiloxane is selected from the group consisting of 1,3,5,7-tetramethylcyclotetrasiloxane (TMCTS), octamethylcyclotetrasiloxane (OMCTS), 1,3,5,7,9-pentamethylcyclopentasiloxane, hexamethylcyclotrisiloxane, and decamethylcyclopentasiloxane.

6. The method of claim 1, wherein the linear hydrocarbon compound comprises one or two carbon-carbon double bonds.

7. The method of claim 1, wherein the linear hydrocarbon compound is ethylene.

8. The Method of claim 1, wherein the linear hydrocarbon compound is selected from the group consisting of ethylene, propylene, isobutylene, acetylene, allylene, ethylacetylene, 1,3-butadiene, isoprene, 2,3-dimethyl-1,3-butadiene, and piperylene.

9. The method of claim 1, wherein the gas mixture includes essentially no oxidizing gas.

10. The method of claim 1, wherein the inert gas is selected from the group consisting of helium, argon, and combinations thereof.

11. The method of claim 1, wherein the applying RF power comprises applying mixed frequency RF power to the gas mixture.

12. The method of claim 1, further comprising post-treating the low dielectric constant film with an electron beam.

13. A method for depositing a low dielectric constant film, comprising:
providing a gas mixture comprising:
a cyclic organosiloxane;
a linear hydrocarbon compound having at least one unsaturated carbon-carbon bond; and
one or more oxidizing gases to a substrate surface; and
applying RF power to the gas mixture at conditions sufficient to deposit a film on the substrate surface, the film having a dielectric constant less than 3.2 and compressive stress.

14. The method of claim 13, wherein the one or more oxidizing gases is selected from the group consisting of oxygen, carbon dioxide, and combinations thereof.

15. The method of claim 13, wherein the one or more oxidizing gases comprises oxygen, and the conditions comprise an oxygen flow rate less than a flow rate of the linear hydrocarbon compound.

16. The method of claim 13, wherein the applying RF power comprises applying mixed frequency RF power to the gas mixture.

17. The method of claim 13, wherein the cyclic organosiloxane is octamethylcyclotetrasiloxane (OMCTS).

18. The method of claim 13, wherein the cyclic organosiloxane is selected from the group consisting of 1,3,5,7-tetramethylcyclotetrasiloxane (TMCTS), octamethylcyclotetrasiloxane (OMCTS), 1,3,5,7,9-pentamethylcyclopentasiloxane, hexamethylcyclotrisiloxane, and decamethylcyclopentasiloxane.

19. The method of claim 13, wherein the linear hydrocarbon compound comprises one or two carbon-carbon double bonds.

20. The method of claim 13, wherein the linear hydrocarbon compound is ethylene.

21. The method of claim 13, wherein the linear hydrocarbon compound is selected from the group consisting of ethylene, propylene, isobutylene, acetylene, allylene, ethylacetylene, 1,3-butadiene, isoprene, 2,3-dimethyl-1,3-butadiene, and piperylene.

22. The method of claim 13, wherein the gas mixture further comprises a gas selected from the group consisting of helium, argon, and combinations thereof.

23. The method of claim 13, further comprising post-treating the low dielectric constant film with an electron beam.

24. A method for depositing a low dielectric constant film, comprising:
providing a gas mixture comprising:
octamethylcyclotetrasiloxane (OMCTS); and
ethylene; and
applying RF power to the gas mixture at conditions sufficient to deposit a film on the substrate surface, the film having a dielectric constant less than 3.0 and compressive stress; and
post-treating the film with an electron beam.

25. The method of claim 24, wherein the gas mixture further comprises one or more oxidizing gases.

26. The method of claim 25, wherein the one or more oxidizing gases is selected from the group consisting of oxygen, carbon dioxide, and combinations thereof.

27. The method of claim 25, wherein the one or more oxidizing gases comprises oxygen, and the conditions comprise an oxygen flow rate less than a flow rate of the ethylene.

28. The method of claim 24, wherein the applying RF power comprises applying mixed frequency RF power to the gas mixture.

29. The method of claim 24, wherein the gas mixture further comprises a gas selected from the group consisting of helium, argon, and combinations thereof.

30. The method of claim 24, wherein the gas mixture includes essentially no oxidizing gas.
